(19) United States
(12) Patent Application Publication
(10) Pub. No.: US 2007/0058749 A1
(43) Pub. Date: Mar. 15, 2007

(54) Modulator

(76) Inventors: Aria Eshraghi, Austin, TX (US); Lysander Lim, Austin, TX (US); Zhongda Wang, Austin, TX (US)

Correspondence Address: TROP PRUNER & HU, PC, 1616 S. VOSS ROAD, SUITE 750, HOUSTON, TX, 77057-2631, US

(21) Appl. No.: 11/227,317

(22) Filed: Sep. 14, 2005

(51) Int. Cl. H04L 25/03; H04L 27/20; H03C 1/06

(52) U.S. Cl. 375/296; 375/308; 375/284; 332/162

(57) ABSTRACT

A technique includes storing in a memory a set of samples that are distorted so that the samples indicate a distorted representation of a modulation signal. The technique includes in response to the set of samples, generating a second signal that includes a substantially less distorted representation of the modulation signal. The distortion of the samples is used to at least partially compensate for a characteristic that is otherwise imparted to the second signal by the act of generating the second signal.

### BACKGROUND

The invention generally relates to a modulator.

Content digital data typically is communicated over a wireless network in the form of radio frequency (RF) carrier signals, which are modulated to indicate the data.

Gaussian Minimum Shift Keying (GMSK) is one form of modulation. Referring to FIG. 1, a conventional GMSK modulator 10 includes a data stream input terminal 12 that receives an incoming stream of “1” and “0” bits; and in response to the incoming bit stream, the GMSK modulator 10 generates a complex modulation waveform that includes two signal components: an in-phase signal (called “I” in FIG. 1) and a quadrature signal (called “Q” in FIG. 1) that are provided at output terminals 27 and 30, respectively, of the modulator 10.

An encoder 14 of the modulator 10 encoding the incoming bit stream into an impulse stream of “+1” and “−1” impulses, which appear at an output terminal 16 of the encoder 14. The impulse stream that is furnished by the encoder 14 is routed through a Gaussian filter 18, and an integrator 20 integrates the resulting filtered signal from the Gaussian filter 18 to produce a signal on an output terminal 22 of the integrator 20. A block 26 takes the cosine of the signal from the terminal 22 to produce the I in-phase signal; and a block 29 takes the sine of the signal from the terminal to produce the Q quadrature signal.

### SUMMARY

In an embodiment of the invention, a technique includes storing in a memory a set of samples that are distorted so that the samples indicate a distorted representation of a modulation signal. The technique includes in response to the set of samples, generating a second signal that includes a substantially less distorted representation of the modulation signal. The distortion of the samples is used to at least partially compensate for a characteristic that is otherwise imparted to the second signal by the act of generating the second signal.

In another embodiment of the invention, a modulator includes a memory to store a set of samples that are distorted so that the samples indicate a distorted representation of a modulation signal. The modulator includes a controller to, response to the set of samples, generate a second signal that includes a substantially less distorted representation of the modulation signal; and the modulator uses the distortion of the samples to at least partially compensate further processing of the second signal.

Advantages and other features of the invention will become apparent from the following drawing, description and claims.

### BRIEF DESCRIPTION OF THE DRAWING

FIG. 1 is a block diagram of a GMSK modulator of the prior art.

FIG. 2 is a block diagram of a GMSK modulator according to an embodiment of the invention.

FIG. 3 is a flow diagram illustrating operation of the GMSK modulator of FIG. 2 according to an embodiment of the invention.

FIG. 4 is a block diagram illustrating an exemplary transmit path of a wireless device according to an embodiment of the invention.

FIG. 5 depicts potential spectral energy that may be present in the modulated signal in the absence of compensation.

FIG. 6 is a flow diagram illustrating a technique to use the GMSK modulator of FIG. 2 to compensate the frequency response of the transmit path according to an embodiment of the invention.

FIG. 7 is an illustration of a sampling technique used in connection with the GMSK modulator of FIG. 2 according to an embodiment of the invention.

FIG. 8 is an output waveform segment that is generated by the GMSK modulator of FIG. 2 according to an embodiment of the invention.

FIG. 9 illustrates a potential transfer function of a digital-to-analog converter.

FIG. 10 is a flow diagram depicting a technique to use the GMSK modulator to compensate the systematic non-linearity of the digital-to-analog converter according to an embodiment of the invention.

FIG. 11 is a schematic diagram of a wireless system according to an embodiment of the invention.

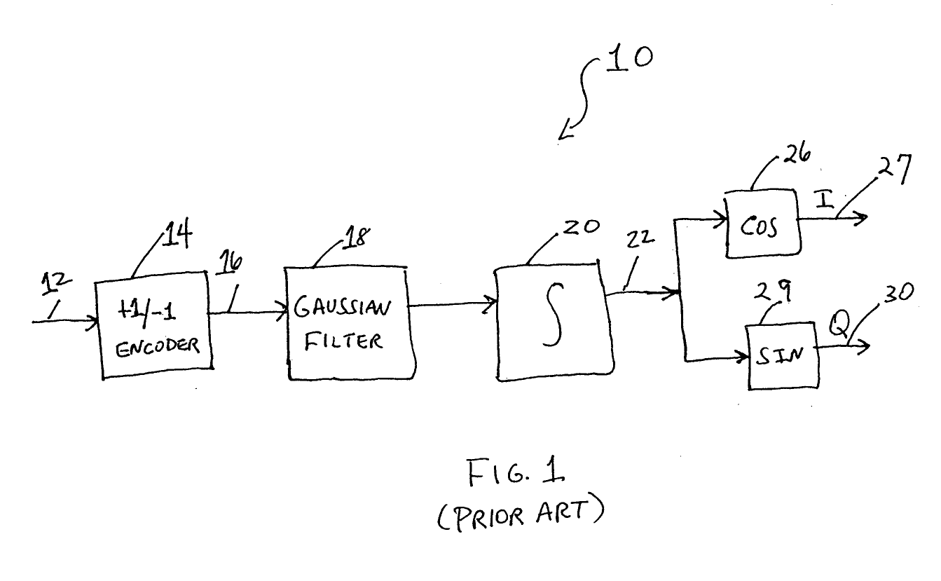

### DETAILED DESCRIPTION

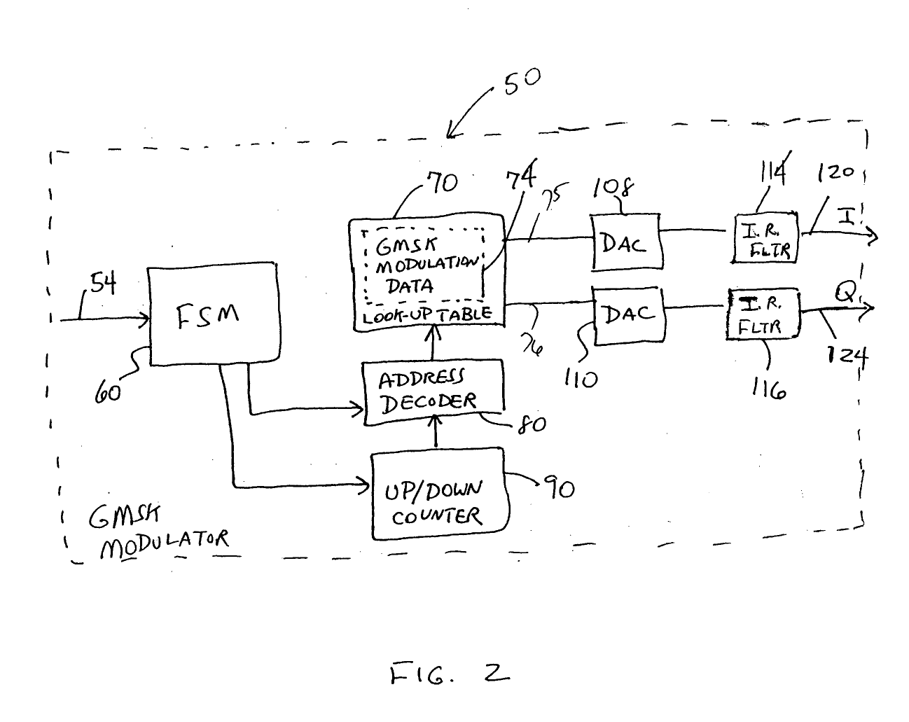

Referring to FIG. 2, a Gaussian Minimum Shift Keying (GMSK) modulator 50 in accordance with some embodiments of the invention receives an incoming data bit stream (at an input terminal 54) and maps the incoming bit stream to a complex GMSK modulation signal (herein called the “modulation signal”). More specifically, the modulator 50 has two terminals that digitally indicate the components of the modulation signal: a terminal 75 that provides a digital signal that represents the in-phase component of the modulation signal and a terminal 76 that provides a digital signal, which represents the quadrature component of the modulation signal.

In some embodiments of the invention, the modulation signal contains spectral energy that spans over a certain frequency band, such as a baseband frequency band; and thus, in some embodiments of the invention, the modulation signal may be a baseband signal. However, the invention is not limited to baseband frequencies and baseband frequency modulators. Thus, in other embodiments of the invention, the modulation signal may have a spectral energy content that extends over a radio frequency (RF) band. Thus, many variations and applications of the modulator 50 are possible and are within the scope of the appended claims.

In accordance with some embodiments of the invention, the modulator 50 digitally synthesizes the modulation signal. In this regard, the modulator 50 takes advantage of the recognition that, in general, a GMSK modulation signal may be represented by a finite collection of output waveform segments. The order in which the segments appear in the modulation signal is a function of the present and recent history of incoming data bit stream. In this regard, the modulator 50 relies on the recognition that a particular time slice of the incoming bit stream produces given I and Q waveforms. Therefore, the modulator 50 processes the incoming data bit stream in time slices, with such time slice being used as an index to select stored I and Q digital waveforms.

More specifically, in accordance with some embodiments of the invention, potential I and Q waveforms are stored in a look-up table 70 of the modulator 50. In this manner, each pair of I and Q waveforms correspond to a particular set of waveform samples that is stored in the GMSK modulation data 74. Thus, each given time slice of the incoming data bit stream signal indexes a set of I and Q samples stored in the look-up table 70. It is noted that for purposes of limiting the storage area for the GMSK modulation data 74, in some embodiments of the invention, every possible incoming data bit waveform does not uniquely correspond to a set of I and Q samples (i.e., a 1:1 mapping may not be used). Rather, the modulator 50, in some embodiments of the invention, may group certain input waveforms together for purposes of determining which set of I and Q samples to use.

The modulator 50 includes a finite state machine (FSM) 60 that analyzes time slices of the incoming data bit stream to match each time slice to a corresponding set of I and Q samples of the GMSK modulation data 74. Based on this match, the FSM 60 controls (as described below) an address decoder 80 and an up/down counter 90 to retrieve the corresponding I and Q samples from the memory 70 so that the samples appear on the terminals 75 and 76.

Digital-to-analog converters (DACs) 108 and 110 of the modulator 50 convert the digital signals that are provided by the terminals 75 and 76, respectively, into corresponding analog signals. These analog signals, in turn, are filtered by image rejection filters 114 and 116 to produce an analog in-phase signal (called “I” in FIG. 2), which appears at an analog output terminal 120 of the modulator 50 and an analog quadrature signal (called “Q” in FIG. 2), which appears at another analog output terminal 124 of the modulator 50.

In accordance with some embodiments of the invention, the GMSK modulation data 74 only stores one half of the I and Q samples for each time slice of the modulation signal because, for each time slice, the I, Q signal is symmetrical about a midpoint of the time slice. The modulator 50 therefore takes advantage of the symmetry to minimize the storage space for the I and Q samples. In doing so, however, the modulator 50 uses two passes to read a given set of I and Q samples from the look-up table 70: a first pass to read the I and Q samples for a particular output waveform segment the table 70 in a first order; and a second pass to retrieve the samples from the look-up table 70 in the opposite, or reverse, order for another output waveform segment. Depending on the current incoming bit stream, the above-described passess may read the same set of I and Q samples twice or may read two different sets of samples (one set of I and Q samples in the forward direction and another set of I and Q samples in the reverse direction).

As a more specific example, in some embodiments of the invention, the modulator 50 may read a particular set of I and Q samples from consecutive memory locations, beginning with reading the first entry of I and Q samples and ending with reading the last entry of I and Q samples. Subsequently, the modulator 50 reads the entries from a particular set of I and Q samples (the same or another set of samples depending on the incoming bit stream) in the reverse order (to generate the remaining symmetrical halves of the I and Q waveforms) by reading the entries from the last entry to the first entry, beginning with the last sample and ending with the first sample.

For purposes of implementing the above-described technique of storing and retrieving the GMSK modulation data 74 from the look-up table 70, the FSM 60 controls operations of the address decoder 80 and the up/down counter 90. More specifically, in accordance with some embodiments of the invention, to retrieve a particular set of I and Q samples from the look-up table 70, the FSM 60 initializes the counter 90, such as an action in which the FSM 60 resets the digital output signal from the counter 90 to be zero. For purposes of initializing the address decoder 80, the FSM 60 may load the starting address or an index pointer to the starting address of the selected set of I and Q samples into the address decoder 80.

In some embodiments of the invention, the counter 90 initially counts in an upward direction to cause the address decoder 80 to generate a sequence of increasing addresses to retrieve the selected set of I and Q samples from the look-up table 70. After the selected set of samples are retrieved (for one half of each of the corresponding I and Q waveforms), the FSM 60 re-initializes the up/down counter 90 to cause the counter 90 to begin counting in a downward direction. In response to the counter's counting in the downward direction, the address decoder 80 decrements the addresses that are provided to the look-up table 70. As a result, the same set of samples is read from the look-up table 70 in the reverse order.

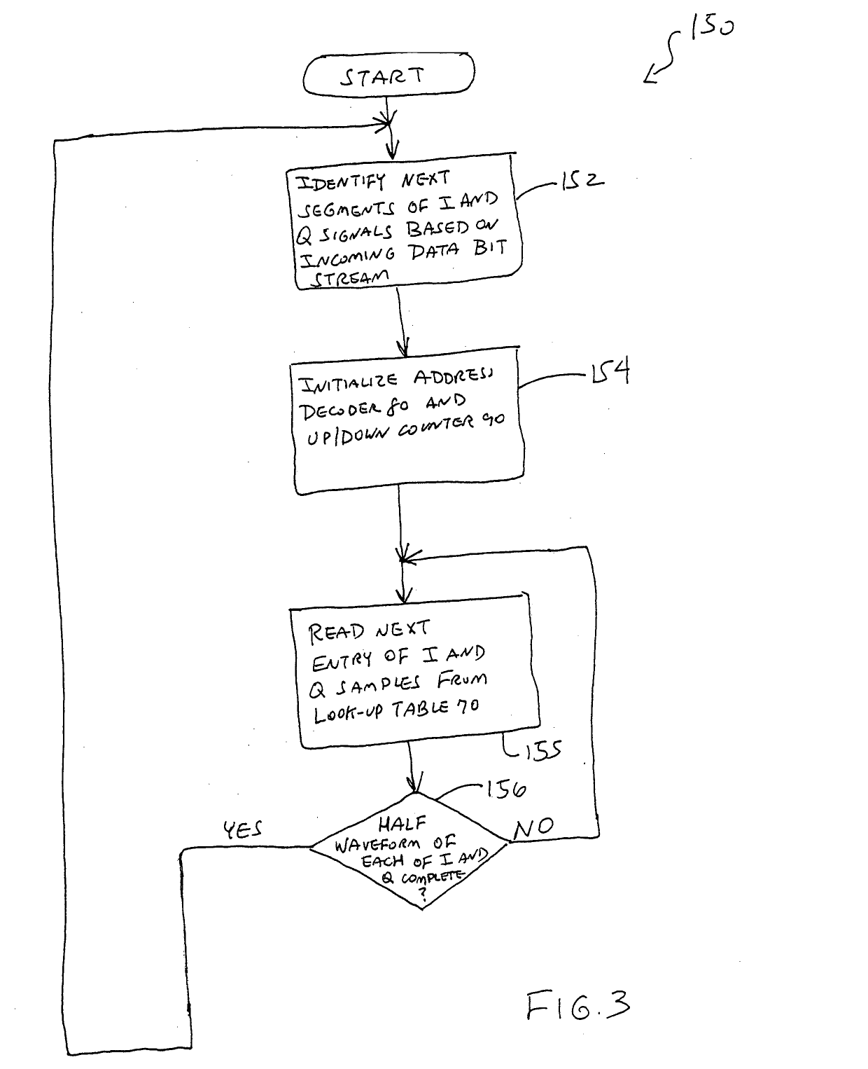

In summary, the modulator 50 may operate pursuant to a technique 150 that is generally depicted in FIG. 3. Pursuant to the technique 150, the FSM 60 identifies (block 152) the next segments of the I and Q signals based on the present and recent past history of the incoming data bit stream. Next, pursuant to the technique 150, the FSM 60 initializes the address decoder 80 with the address of the selected set of samples and initializes the counter 90, as depicted in block 154. The initialization of the counter 90 includes initializing the counter 90 to count in a particular direction, such as a direction in which the output signal from the counter 90 increases in value with each count. FSM 60 then begins reading the I and Q entries from the look-up table 70, as depicted in block 155. The read I and Q samples are provided to the output terminals 75 and 76. The reading of the I and Q samples continues until the FSM 60 determines (diamond 156) that each of the I and Q waveforms are complete. Next, the FSM 60 allows the continued retrieval of the samples from the look-up table 70.

If generation of one half of the output waveform segment is complete, then the FSM 60 returns to block 152 where the FSM 60 targets a set of I and Q samples (pursuant to block 152); and the FSM 60 intializes the counter 90 to count in the opposite direction and initializes the address decoder 80 with an address for the targeted set of I and Q samples.

Thus, in some embodiments of the invention, the direction in which the samples are read from the look-up table 70 alternates each times another pass occurs through the blocks 152, 154, 155 and 156.

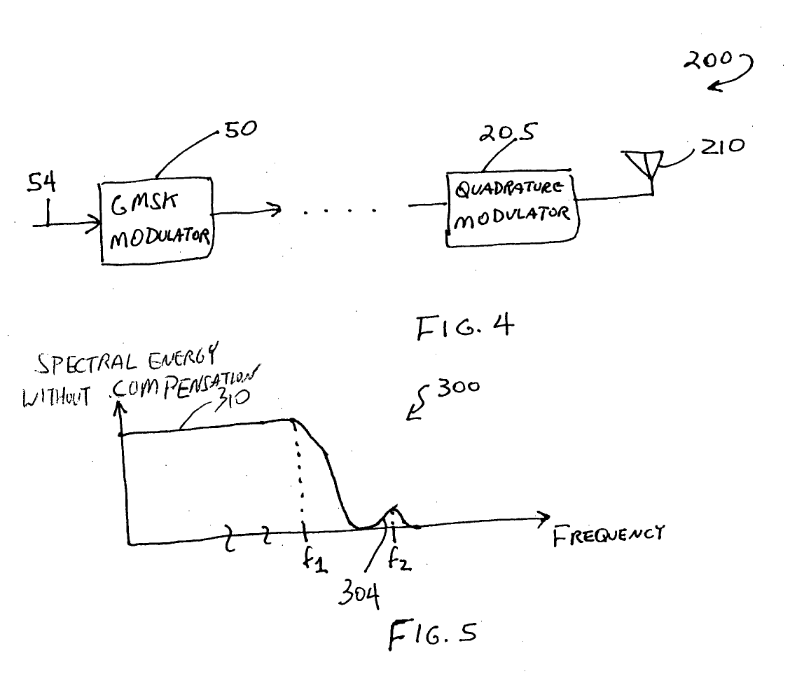

Referring to FIG. 4, in accordance with some embodiments of the invention, the modulator 50 may be part of a transmit path 200 of a wireless system. As an example, in accordance with some embodiments of the invention, the GMSK modulator 50 may generate a baseband modulation signal. The baseband modulation signal that is provided by the GMSK modulator 50 may ultimately be modulated by a quadrature modulator 205. The quadrature modulator 205, in turn, may translate the baseband modulation signal to RF frequencies for purposes of forming a modulated RF carrier signal to be communicated to a wireless network by an antenna 210.

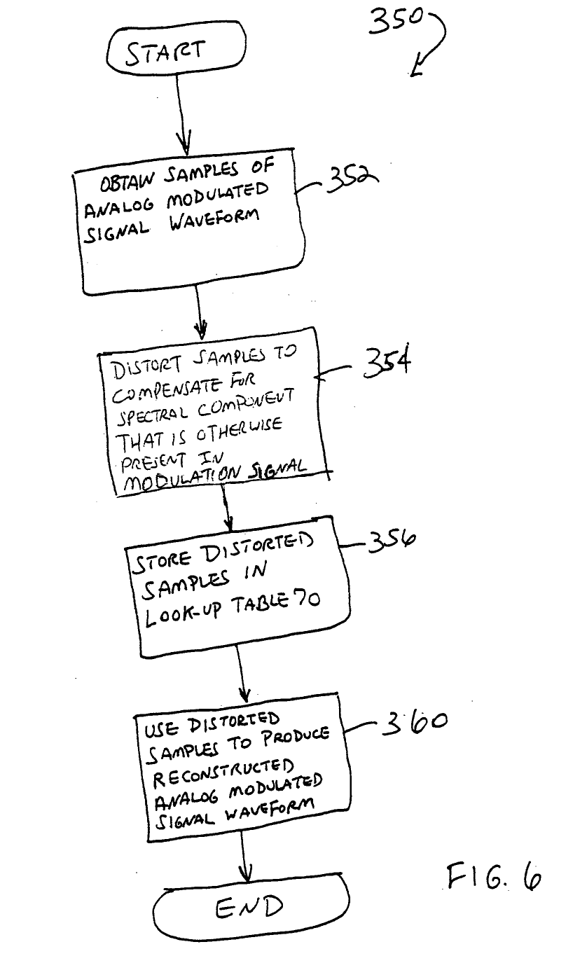

In accordance with some embodiments of the invention, the modulation signal that is produced by the GMSK modulator 50 may have a spectral energy that ideally is contained with a given frequency band. However, because the look-up table 70 stores a finite, or limited set of samples, the modulation signal may contain inherent distortion, which introduces spectral energy beyond the targeted band. This may present problems in that this spectral energy may ultimately interfere with an alternate adjacent frequency band generated by another wireless system. More particularly, referring also to FIG. 5, if not for the features of the modulator 50 that are described herein, a spectral energy 300 of the modulation signal that is produced by the modulator 50 may include spectral energy 310 that is generally confined within a band (whose upper limit appears at a frequency called “f₁”) and an additional unwanted spectral component 304 that appears at a higher out-of-band frequency (called “f₂” in FIG. 5). Due to the spectral component 304, unwanted noise may appear in an alternate frequency band.

For purposes of preventing the out-of-band spectral component 304 from appearing in the modulation signal that is produced by the modulator 50, the GMSK modulation data 74 (see FIG. 2) is purposefully pre-distorted to cancel, if not significantly diminish, the spectral component 304.

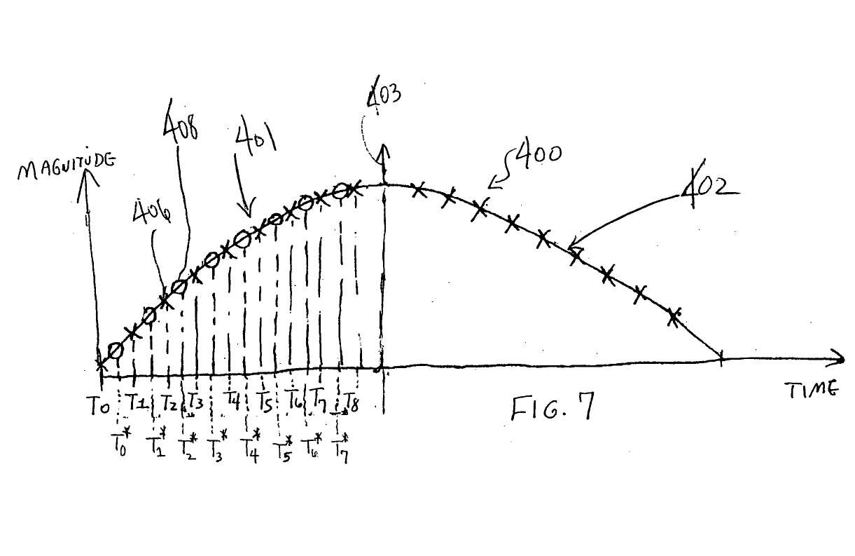

Referring to FIG. 6, to summarize, a technique 350 may be used in connection with the modulator 50 in accordance with some embodiments of the invention. The technique 350 includes obtaining (block 352) samples of a modulated signal waveform. The samples are distorted (block 354) to compensate for an undesired spectral component that may otherwise be present in the modulation signal. These distorted samples are stored in the lookup table 70, as depicted in block 356. The distorted samples are then used (block 360) by the modulator 50 to produce a reconstructed modulated signal waveform, a waveform that whose spectral frequency components are within the desired band.

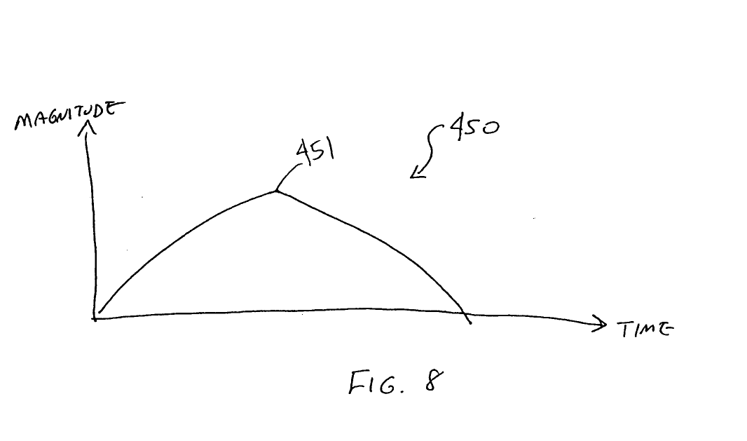

FIG. 7 illustrates a technique that may be used to pre-distort the GMSK modulation data 74 in accordance with some embodiments of the invention. In particular, FIG. 7 depicts an exemplary output waveform segment 400 (a segment of the I or Q signal) of the modulation signal and illustrates the associated samples that are stored in the GMSK modulation data 74, as further described below. The waveform segment 400 may be viewed as being divided into two portions 401 and 402 that are symmetrical about a midpoint 403. Thus, to generate the portion 401, samples that correspond to times T₀ to time T₇ may be read from the lookup table 70 in sequence; and to generate the portion 402, the samples that correspond to times T₇ to time T₀ are read from the look-up table 70 in sequence.

Times T₀-T₇ represents uniform sampling times, i.e., times at which corresponding samples (such as an exemplary sample 406 that corresponds to uniform sampling time T₂) may be provided at the output of the modulator 50 to reproduce a non-distorted version of the portion 401 or 402 of the output waveform segment 400. Although the modulator 50 reproduces a corresponding output waveform segment pursuant to uniform sampling times that correspond to the uniform sampling times T₀-T₇, the GMSK modulation data 74 is purposefully time-shifted to distort the samples. More specifically, as depicted in FIG. 7, the first half 401 of the waveform 400 is, instead of being sampled at the sampled points that correspond to the uniform sampling times T₀-T₇, sampled at times T₀*-T₇*, which are time-shifted versions of times T₀-T₇. Therefore, although the samples are taken at times T₀*-T₇*, the modulator 50 uses the uniform sampling times T₀-T₇ to reproduce a version of the output waveform segment 408 at its output.

As a more specific example, exemplary sampling time T₂ corresponds to exemplary sample 406 if no distortion is introduced. However, instead of storing the sample 406 in the GMSK modulation data 74, exemplary sample data 408, taken at time T₂*, is instead used and thus, stored as part of the GMSK modulation data 74.

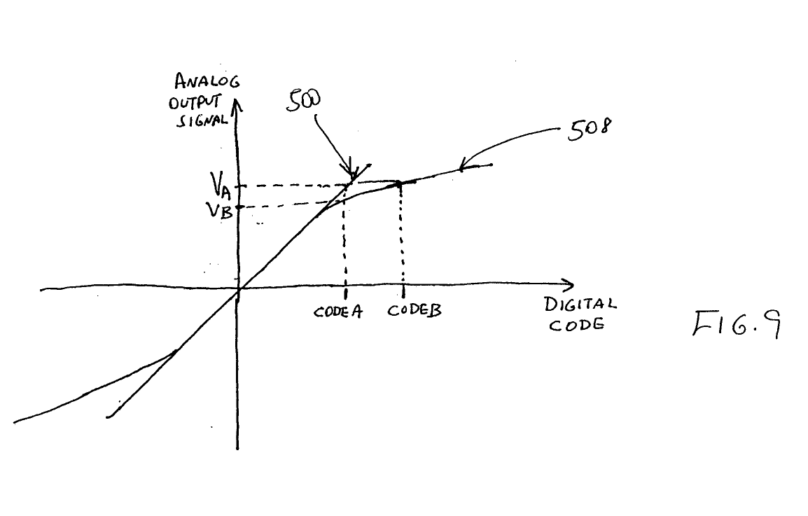

Referring to FIG. 8, the above-described time shifting of the samples causes the modulator 50 to produce a waveform segment 450. Contrasting the waveform segment 400 of FIG. 7 with the waveform 450 segment, the waveform 450 is distorted in time in that the waveform 450 includes a discontinuous peak 451 at its midpoint. This distortion in the time domain, in turn, compensates the frequency domain of the modulation signal.

Thus, as described above, the GMSK modulation data 74 (see FIG. 2) may be time-shifted for purposes of distorting the modulation signal to eliminate if not significantly reduce out-of-band spectral energy.

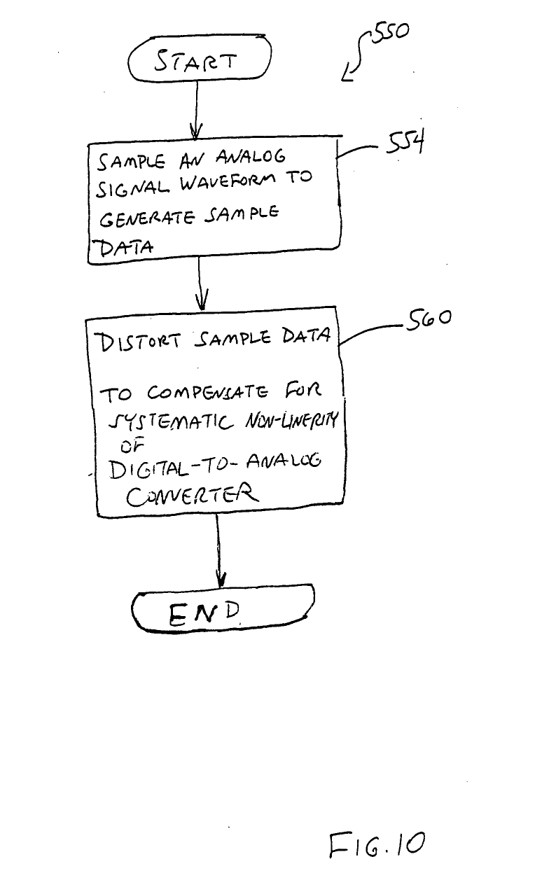

The GMSK modulation data 74 may also be pre-distorted for purposes of compensating for characteristics other than frequency characteristics that are introduced downstream of the modulator 50. For example, referring to FIG. 2 in conjunction with FIG. 9, the DAC 108, 110 may have a systematic non-linear transfer function 508, which is a relationship between the analog output signal from the DAC 108, 110 and the digital code that is received at the input terminals of the DAC 108, 110. Ideally, a DAC has a linear transfer function 500. In general, the closer the transfer function of a DAC is to an ideal linear transfer function is a function of the complexity and die area of the DAC. However, by pre-distorting the GMSK modulation data 74 to compensate for the non-linearity of a DAC, a significantly less complex and smaller DAC may be used.

More specifically, in accordance with some embodiments of the invention, the magnitudes of the sample values of the GMSK modulation data 74 are pre-distorted to account for the non-linearity of the DAC 108, 110. For example, a particular digital input code called “Code A” in FIG. 9 that is received by the DAC 108, 110 should ideally produce an certain analog output voltage (called “V_{A}” in FIG. 9) from the DAC 108, 110. However, due to the non-linearity of the DAC 108, 110, the DAC 108, 110 instead produces an analog output voltage called “V_{B}” in FIG. 9.

To compensate for the difference between the ideal linear and non-ideal non-linear response of the DAC 108, 110, the samples that are stored in the look-up table 70 are pre-distorted in amplitude, in some embodiments of the invention. Thus, in some embodiments of the invention, the samples are both time-shifted for purposes of frequency compensation and are amplitude adjusted to compensate for the systematic non-linearity of each of the DACs 108 and 110.

Therefore, for the example that is depicted in FIG. 9, although Code A is the correct code for a linear DAC, Code A is pre-distorted to be a large digital value called “Code B.” As depicted in FIG. 9, in view of the non-linear transfer function 508, Code B produces the V_{A} analog output voltage from the DAC 108, 110. Therefore, by pre-distorting the GMSK modulation data 74 in the appropriate manner, the pre-distorted data effectively produces a linear transfer function for the DAC 108, 110.

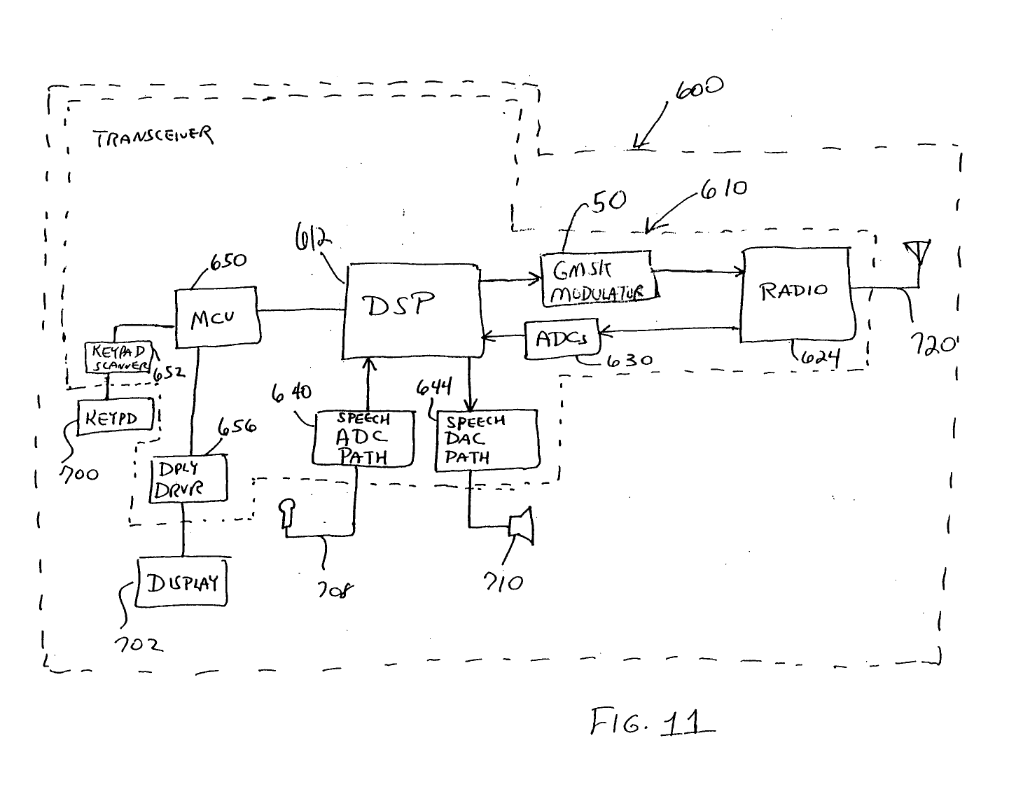

To summarize, FIG. 10 depicts a technique 550 that may be used in accordance with some embodiments of the invention. Pursuant to the technique 550, an analog signal waveform is sampled (block 554) to generate sampled data. This sampled data is distorted (block 560) to compensate for the re-occurring, or systematic, non-linearity of a digital-to-analog converter. The technique 550 may be used in connection with the technique 350 (see FIG. 6) to produce the GMSK modulation data 74 for the look-up table 70 which compensates the spectral frequency of the modulation signal as well as compensates for the systematic non-linearity of the DACs 108 and 110.

Referring to FIG. 11, the GMSK modulator 50 may be used in a wireless system 600 in accordance with some embodiments of the invention. The wireless system 600 may include a transceiver 610 that is coupled to a microphone 708 for purposes of receiving an input speech signal and a speaker 710 for purposes of producing an audio sound from the system 600. Depending on the particular embodiment of the invention, the transceiver 610 may also be coupled to a keypad 700 to receive input user data and a display 702 for purposes of displaying applications, content data, etc., on the wireless device 600. Furthermore, the transceiver 610 may be coupled to an antenna 720 for purposes of communicating modulated RF carrier with a wireless network.

Depending on the particular embodiment of the invention, the wireless system 600 may be, as examples, a handheld device such as a personal digital assistant (PDA) or a cellular telephone. In other embodiments of the invention, the wireless system 600 may be a notebook or a less portable device, such as a desktop computer (as an example).

The transceiver 610 may be fabricated on a single die that is part of a semiconductor package in accordance with some embodiments of the invention. However, in other embodiments of the invention, the transceiver 610 may be fabricated on multiple dies on a single semiconductor package, may be formed from more than one semiconductor package, etc. Thus, many variations are possible and are within the scope of the appended claims.

The GMSK modulator 50 may receive its incoming bit stream from a digital signal processor (DSP) 612 of the modulator 50. As depicted in FIG. 11, the modulator 50 provides the modulation signal to a radio 624.

For transmissions, the radio 624 receives the modulation signal from the modulator 50 and translates the baseband frequencies to RF frequencies for purposes of transmitting a modulated RF carrier signal over a wireless network via the antenna 720. For purposes of receiving content from the wireless network, the radio 624 may receive a modulated RF carrier signal from the antenna 720 and translate the RF frequencies of the signal to baseband frequencies to produce an analog modulated baseband signal that is provided to analog-to-digital converter (ADCs) 630. The ADCs 630 convert the analog modulated baseband signal from the radio 624 into a digital signal that is processed by the DSP 612. The DSP 612 may implement a de-modulator for purposes of recovering content from the received signal.

Among the other features of the transceiver 610, in accordance with some embodiments of the invention, the transceiver 610 may include a microcontroller unit (MCU) 650 that may be coupled to the DSP 612 to generally control and coordinate operations of the transceiver 610. Depending on the particular embodiment of the invention, the MCU 650 may be coupled to a keypad scanner 652 that receives signals from the keypad 700 and a display driver 656 that generates signals to drive the display 702. As also depicted in FIG. 11, the transceiver 610 may include a speech ADC path 640 for purposes of processing a speech signal received from the microphone 708 and a speech DAC path 644 for purposes of converting a digital speech signal into an analog audio signal that is provided to the speaker 710.

It is noted that FIG. 11 depicts one out of many possible wireless systems in accordance with the numerous possible embodiments of the invention. It is noted that in other embodiments of the invention, other wireless systems may incorporate the GMSK modulator, architectures for the GMSK modulator other than the one that is depicted in FIG. 2 may be used.

While the present invention has been described with respect to a limited number of embodiments, those skilled in the art, having the benefit of this disclosure, will appreciate numerous modifications and variations therefrom. It is intended that the appended claims cover all such modifications and variations as fall within the true spirit and scope of this present invention.

What is claimed is:

1. A method comprising:
storing in a memory a set of samples being distorted so that the samples indicate a distorted representation of a modulation signal;
in response to the set of samples, generating a second signal that comprises a substantially less distorted representation of the modulation signal; and
using the distortion of the samples to at least partially compensate for a characteristic otherwise imparted to the second signal by the act of generating the second signal.

2. The method of claim 1, wherein the characteristic comprises out-of-band spectral energy.

3. The method of claim 1, wherein the characteristic is attributable to a limited number of the samples.

4. The method of claim 1, wherein the characteristic comprises spectral energy located outside a channel associated with the modulation signal.

5. The method of claim 1, further comprising:
sampling a waveform indicative of the substantially less distorted representation of the modulation signal to produce sampled values; and
modifying the sampled values to generate the set of samples.

6. The method of claim 5, wherein the act of modifying comprises time-shifting the sampled values to generate the set of samples.

7. The method of claim 1, wherein the modulation signal comprises a Gaussian Minimum Shift Keying modulation signal.

8. A method comprising:
storing in a memory a set of samples being distorted so that the samples indicate a distorted representation of a modulation signal;
in response to the set of samples, generating a second signal; and
using the distortion of the samples to at least partially compensate further processing of the second signal.

9. The method of claim 8, wherein the act of using comprises:
using the distortion of the samples to compensate for a systematic non-linearity introduced by a digital to analog converter.

10. The method of claim 8, wherein the set of samples comprise a set of amplitudes modified from another set of amplitudes associated with another set of samples indicative of a significantly less distorted representation of the modulation signal.

11. The method of claim 8, further comprising:
sampling a waveform indicative of the substantially less distorted representation of the modulation signal to produce sampled values; and
modifying amplitudes of the sampled values to generate the set of samples.

12. A modulator comprising:
a memory to store a set of samples being distorted so that the samples indicate a distorted representation of a modulation signal; and
a controller to:
in response to the set of samples, generate a second signal that comprises a substantially less distorted representation of the modulation signal, and
use the distortion of the samples to at least partially compensate for a characteristic otherwise imparted to the second signal by the generation of the second signal.

13. The modulator of claim 12, wherein the characteristic comprises spectral energy.

14. The modulator of claim 12, wherein the characteristic is attributable to a limited number of the samples.

15. The modulator of claim 12, wherein the characteristic comprises spectral energy located outside a channel associated with the modulation signal.

16. A modulator comprising:
a memory to store a set of samples being distorted so that the samples indicate a distorted representation of a modulation signal; and
a controller to:
in response to the set of samples, generate a second signal that comprises a substantially less distorted representation of the modulation signal, and
use the distortion of the samples to at least partially compensate further processing of the second signal.

17. The modulator of claim 16, wherein the distortion of the samples compensate for a systematic non-linearity introduced by a digital to analog converter.

18. The modulator of claim 16, wherein the set of samples comprise a set of amplitudes modified from another set of amplitudes associated with another set of samples indicative of a significantly less distorted representation of the modulation signal.

19. A system comprising:
a radio to respond to a baseband signal; and
a modulator to:
select a set of samples in response to an input signal, the samples being distorted so that the samples indicate a distorted representation of a modulation signal,
generate the baseband signal in response to the selected set of samples, the baseband signal comprising a substantially less distorted representation of the modulation signal, and
use the distortion of the samples to at least partially compensate for a characteristic otherwise imparted to the second signal by the generation of the second signal.

20. The system of claim 19, wherein the modulator comprises a Gaussian Minimum Shift Keying modulator.

21. The system of claim 19, wherein the characteristic comprises spectral energy.

22. The system of claim 19, wherein the characteristic is attributable to a limited number of the samples.

23. The system of claim 19, wherein the characteristic comprises spectral energy located outside a channel associated with the modulation signal.

24. A system comprising:
a circuit to process a baseband signal and provide a processed baseband signal;
a radio to receive the processed baseband signal; and
a modulator to:
select a set of samples in response to an input signal, the samples being distorted so that the samples indicate a distorted representation of a modulation signal,
generate the baseband signal in response to the selected set of samples, the baseband signal comprising a substantially less distorted representation of the modulation signal, and
use the distortion of the samples to at least partially compensate for a characteristic of the circuit.

25. The system of claim 24, wherein the circuit comprises a digital to analog converter and the distortion of the samples compensates for a systematic non-linearity of the digital to analog converter.

26. The system of claim 24, wherein the modulator comprises a Gaussian Minimum Shift Keying modulator.
